(19) United States
(12) Patent Application Publication
(10) Pub. No.: US 2009/0152648 A1
(43) Pub. Date: Jun. 18, 2009

(54) Semiconductor Device and Method of Fabricating the Same

(76) Inventor: Yong Soo Cho, Daejeon (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/331,342

(22) Filed: Dec. 9, 2008

(30) Foreign Application Priority Data
Dec. 17, 2007 (KR) 10-2007-0131938

(51) Int. Cl. H01L 29/78; H01L 21/336

(52) U.S. Cl. 257/408; 257/413; 438/296; 257/E29.266; 257/E29.273; 257/E21.437

(57) ABSTRACT

Disclosed are a semiconductor device and a method of fabricating the same. The semiconductor device includes a gate electrode that includes a body part disposed on the semiconductor substrate and a projecting part projecting downward from the body part; and source/drain regions at opposite sides of the gate electrode.

The present application claims priority under 35 U.S.C. 119 to Korean Patent Application No. 10-2007-0131938 (filed on Dec. 17, 2007), which is hereby incorporated by reference in its entirety.

### BACKGROUND

1. Field of the Invention

The embodiments of the present invention relate to semiconductor devices and methods of fabricating the same.

2. Description of the Related Art

A semiconductor device recently used for wireless communication devices, etc., may be operated at a voltage of from 3 V to 5 V. Also, a small and highly integrated semiconductor device is needed.

### SUMMARY OF THE INVENTION

The embodiments of the present invention provide semiconductor devices that can be operated at high voltages and can be highly integrated.

There is provided a semiconductor device generally comprising: a semiconductor substrate; a gate electrode that includes a body part on the semiconductor substrate and a projecting part projecting downwardly from the body part; and source/drain regions in the substrate at opposite sides of the gate electrode.

There is also provided a method of fabricating a semiconductor device comprising the steps of: forming a groove on or in a semiconductor substrate; forming a gate electrode comprising a body part on the semiconductor substrate and a projecting part projecting downwardly from the body part; and forming source/drain regions at opposite sides of the gate electrode.

According to embodiments of the present invention, the semiconductor device may also have a channel length, which may be at or below a lower part (e.g., a lowermost surface)of the gate electrode. The channel length is generally increased by the projecting part of the gate electrode relative to a conventional CMOS transistor having a gate with a planar lowermost surface.

The semiconductor device may operate at a higher voltage as the channel length increases.

Also, in the present semiconductor device according to the embodiment, even though the length between the source/drain regions is reduced, the length of the channel is longer by the projecting part of the gate electrode, making it possible to reduce the size of the semiconductor device.

### BRIEF DESCRIPTION OF THE DRAWINGS

FIG. 1 is a cross-sectional view of an exemplary MOS transistor according to embodiments of the present invention; and

FIGS. 2A to 2E are cross-sectional views showing an exemplary method for fabricating an NMOS transistor according to embodiments of the present invention.

### DETAILED DESCRIPTION OF THE EMBODIMENTS

A semiconductor device and a method for manufacturing the same according to embodiments of the present invention will be described in detail with reference to the accompanying drawings.

In the description of various embodiments, it will be understood that when a layer (or film) is referred to as being “on” another layer or substrate, it can be directly on another layer or substrate, or one or more intervening layer may also be present.

FIG. 1 is a cross-sectional view of an exemplary MOS transistor according to embodiments of the present invention.

Referring to FIG. 1, the MOS transistor generally comprises a semiconductor substrate 100, a gate electrode 200, a gate insulating layer 230, a spacer 240, a lightly doped drain (LDD) region 300, source/drain regions 400, and a silicide layer 500.

The semiconductor substrate 100 may comprise a single crystal silicon substrate (e.g., a wafer), which may have one or more layers of Si, strained Si, or Si—Ge thereon (e.g., epitaxial Si and/or SiGe). Additionally, the semiconductor substrate 100 may include a region 100 that includes a lightly doped n-type region 110, a device isolating layer 130, and a p-type well 120.

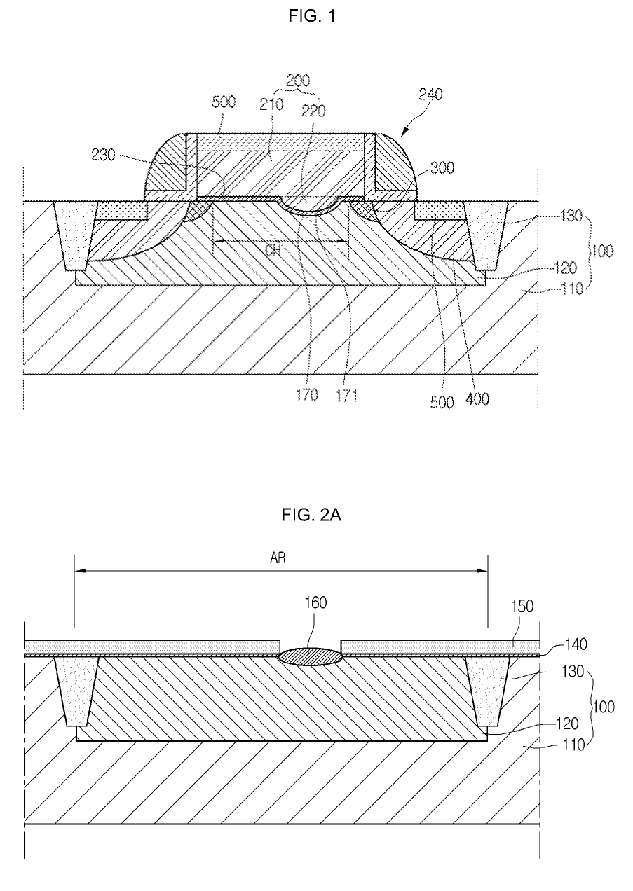

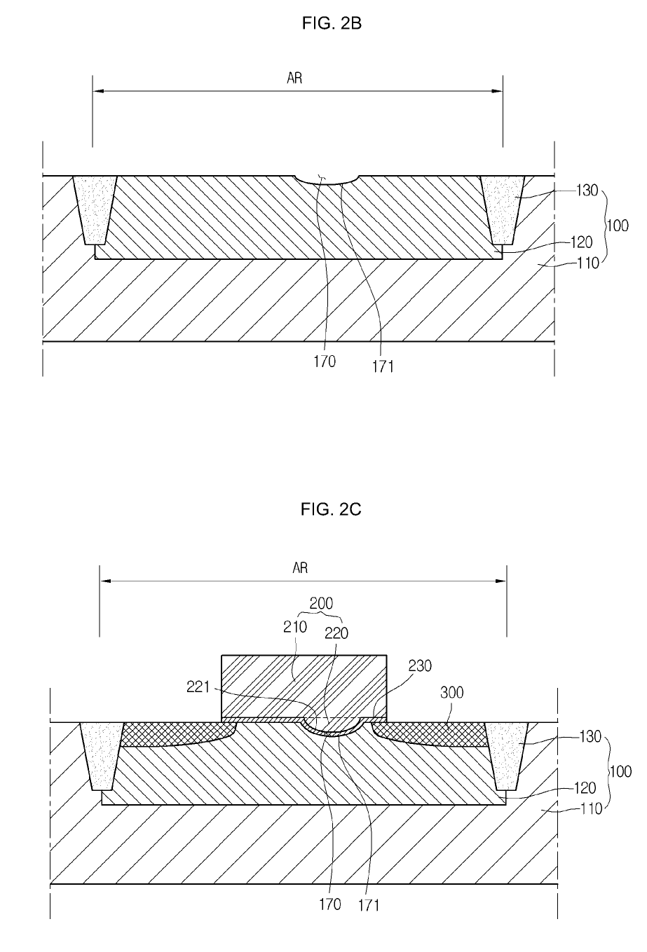

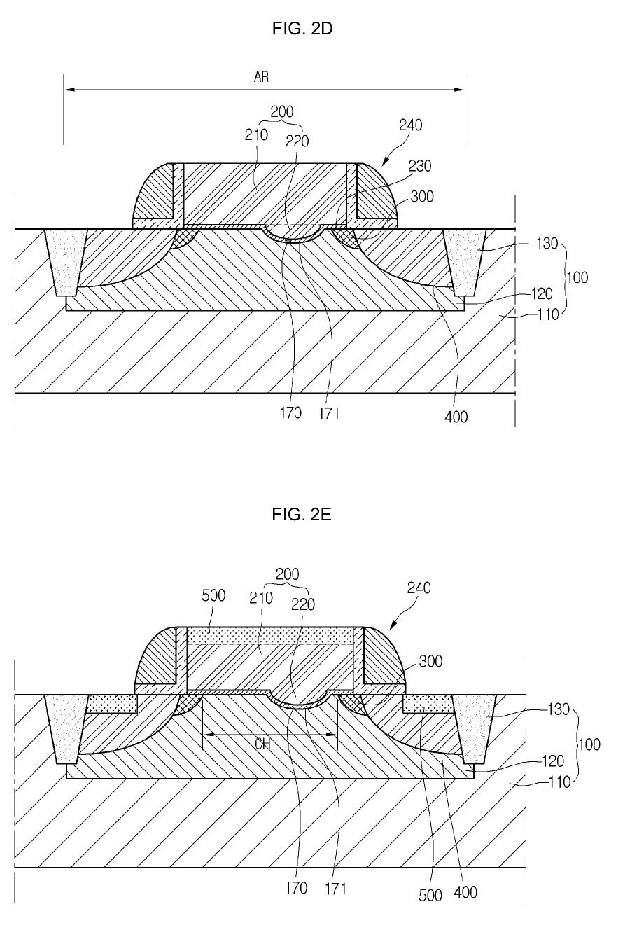

The device isolating layer 130 may be formed by a LOCOS process and/or an STI process, etc., to isolate the semiconductor devices. The semiconductor substrate 100 may further comprise an active region (AR) (see FIG. 2A), which may be defined by the device isolating layer 130.

The p-type well 120 is generally formed in the activation region (AR) and by implanting a low-concentration of p-type impurity (e.g., B, Ga, In, Tl, etc.).

Also, the semiconductor substrate 100 comprises a groove 170. The groove 170 is formed on or in the p-type well 120, and at least a portion of an inner side 171 of the groove 170 has a curved surface. More specifically, the groove 170 is has a greater length in one direction on the semiconductor substrate 100. Additionally or alternatively, the entire inner side 171 of the groove 170 may have a curved surface.

A gate electrode 200 is formed on the active region (AR) of the semiconductor substrate 100. Preferably, the gate electrode 200 is formed on or in the groove 170. The gate electrode 200 may comprise polycrystalline silicon and/or a metal, such as tungsten, molybdenum, cobalt, titanium, a silicide thereof, or aluminum or an aluminum alloy (e.g., Al with up to 4 wt. % Cu, up to 2 wt. % Cu, up to 2 wt. % Ti, and/or up to 1 wt. % Si). The metal may be on conventional adhesion and/or barrier layers (e.g., Ti and/or TiN, such as a TiN-to-Ti bilayer), and/or may be covered by conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer. In exemplary implementations, the gate electrode 200 includes a body part 210 and a projecting part 220.

The body part 210 of the gate electrode 200 is on/in the semiconductor substrate 100, and generally has a rectangular shape. The body part 210, may for example, have a greater length in one direction than width in an orthogonal direction, and the body part 210 covers the groove 170.

The projecting part 220 of the gate electrode 200 is integrally formed with the body part 210 and generally projects downward. In preferred embodiments, the projecting part has a curved surface, complementary to that of the groove 170. The projecting part 220 may have a length in the same direction as the body part 210, greater than the width or thickness, and the projecting part 220 may correspond to the groove 170. For example, the projecting part 220 may be inside the groove 170 and may have a curved surface complementary to the groove 170.

The gate insulating layer/film 230 is between the gate electrode 200 and the semiconductor substrate 100. In various implementations, the gate insulating film 230 may comprise any suitable material known in the art, such as an oxide (e.g., thermal SiO₂). A portion of the gate insulating film 230 is inside the groove 170 and at a lower part of the projecting part 220. In general, the gate insulating layer 230 insulates the gate electrode 200 and the semiconductor substrate 100 from each other.

A spacer 240 may be disposed at or on one or more side (s) of the gate electrode 200. The spacer 240 may comprise a material such as tetraethyl orthosilicate (TEOS), nitride, a combination thereof, or any other suitable material for insulating the side(s) of the gate electrode 200 and serving as a mask during source/drain terminal implantation.

LDD regions 300 are formed in the well 120, adjacent to a lower part of the gate electrode 200. The LDD region 300 comprises a low-concentration of n-type impurities (e.g., phosphorus, arsenic, antimony, etc.). In exemplary embodiments, the transistor/semiconductor device comprises a pair of LDD regions, and the LDD regions are spaced apart from one another by the gate 200 and device isolation regions 130.

In some embodiments, a channel region (CH) is formed between the LDD region(s) 300 and below a lower part of the gate electrode 200.

Source/drain regions 400 are formed at opposite sides of the gate electrode 200. Furthermore, the source/drain regions 400 may include a high-concentration of n-type impurities. Also, the source/drain regions 400 are adjacent to the LDD regions 300.

A silicide layer 500 may be formed on the gate electrode 200 and/or the source/drain regions 400. The silicide layer 500 may comprise nickel (Ni) silicide or titanium (Ti) silicide. The silicide layer 500 improves an electrical connection of contact electrodes that are electrically connected to each of the source/drain region 400 and the gate electrode 200.

The NMOS transistor/semiconductor device according to embodiments of the present invention advantageously has a channel length that is relatively long as a result of the groove 170 and the projecting part 220. Therefore, the NMOS transistor according to the present invention may prevent a punch through phenomenon to the channel region (CH), even when high voltage is applied to the source/drain regions 400.

The present NMOS transistor can be operated at a high voltage.

Furthermore, since the groove 170 and the projecting part 220 include a curved surface, it is possible to reduce an amount of electrons flowing in the gate electrode 200. In other words, since the gate insulating layer 230 inside the groove 170 has a curved surface complementary to the groove 170, electrons passing through the channel region (CH) may collide on the insulating layer, but do not pass through the gate insulating layer 230. Therefore, the performance of the present NMOS transistor is not degraded.

In addition, the channel length may be increased by the groove 170 and the projecting part 220, and thus the width of the gate electrode 200 may be reduced. In other words, when compared to a conventional NMOS transistor that does not have the groove 170 and the projecting part 220, the width of the gate electrode of the present NMOS transistor may be reduced. Therefore, the size of the present NMOS transistor may be relatively small and may be highly integrated.

FIGS. 2A to 2E are cross-sectional views showing an exemplary method of fabricating a NMOS transistor/semiconductor device.

Referring to FIG. 2A, a low concentration of p-type impurity is selectively implanted into a silicon substrate that includes a low-concentration n-type impurity, such that a region including an n-type impurity 110 and a p-type well 120 is formed in the substrate 100.

Thereafter, a trench is patterned and etched in the substrate between the p-type well 120 and the region 110, including the n-type impurity 110. An insulating material (e.g., silicon dioxide) is deposited in the trench to form one or more device isolating layer(s) 130. The activation region (AR) may be defined by the device isolating layer(s) 130. Thereby, the semiconductor substrate 100, which includes a region including the n-type impurity 110, the p-type well 120, and the device isolating layer 130, is formed.

Thereafter, at least one insulating layer (e.g., a first oxide layer 140 and/or a nitride layer 150) may be deposited on the semiconductor substrate 100. The insulating layers (e.g., first oxide layer/film 140 and nitride layer 150 of FIG. 2A) may then be selectively etched to expose a portion of the p-type well 120. Generally, the exposed portion of the p-type well 120 may have a greater length in one direction than the width in an orthogonal directional (shown).

Thereafter, a portion of the exposed p-type well 120 may be oxidized, and a second oxide layer 160 may be formed by a thermal oxidation process. Specifically, a portion of the exposed p-type well 120 reacts with oxygen to form the second oxide layer 160. Prior to oxidation, a small recess may be etched into the p-type well 120.

Referring to FIG. 2B, the first oxide layer 140, the nitride layer 150, and the second oxide layer 160 are removed, forming the groove 170 on/in the semiconductor substrate 100. Groove 160 may have a depth of from 100 to about 1000 Å, preferably 150-500 Å.

In one aspect, the groove 170 has a curved surface. In other words, the central portion of the groove 170 is deeper than the edge(s) of the groove 170. Furthermore, an entire inner side 171 of the groove 170 may have a curved surface, and the groove 170 may have a greater length than width.

Referring to FIG. 2C, after the groove 170 is formed, a third oxide layer is formed on the semiconductor substrate 100. The third oxide layer is formed inside the groove 170, and is complementary to the inner side 171 of the groove 170.

Thereafter, the polysilicon layer is formed on the third oxide layer. The polysilicon layer fills the inside of the groove 170. The body part of the polysilicon layer may be from 1500 to 8000 Å. Then, the third oxide layer and the polysilicon layer are patterned by a mask process to form a gate insulating layer 230 and a gate electrode 200. The gate electrode 200 comprises a body part 210 and a projection 200 projecting downwardly from the body part 210. The gate insulating layer 230 is between the gate electrode 200 and the semiconductor substrate 100.

The projecting part 220 of the gate electrode may be complementary to the groove 170, and may have a greater length in one direction corresponding to the groove 170. Furthermore, the projecting part 220 of the gate electrode may have a curved surface 221.

Thereafter, a low-concentration of n-type impurities may be implanted into the activation region (AR) using the gate electrode 200 as a mask. The implanted n-type impurity may be then diffused by a heat treatment (or annealing) process to form a LDD region 300.

Referring to FIG. 2D, a spacer 240 is formed on the side(s) of the gate electrode 200 by depositing one or more films (e.g., a TEOS film and/or a nitride film) on the substrate. Such films may be sequentially stacked on the active region (AR) of the substrate, and the TEOS film and the nitride film may be etched by an anisotropic etching process.

Thereafter, a high-concentration of n-type impurity is implanted into the activation region (AR) using the spacer 240 as an ion implantation mask. The implanted high-concentration n-type impurity may then be diffused into the side (s) of the active region (AR) by a heat treatment process or any other process known in the art, to form source/drain regions 400 at opposite sides of the gate electrode 200.

Referring to FIG. 2E, a non-reacting metal layer is formed on the activation region (AR) and a silicide layer 500 is formed on the gate electrode 200 and the source/drain regions 400 by a rapid temperature process (RTP), etc.

Hereinafter, the non-reacting metal layer is removed by a cleaning process.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate;
a gate electrode comprising a body part on the semiconductor substrate and a projecting part projecting downwardly from the body part; and
source/drain regions in the semiconductor substrate at opposite sides of the gate electrode.

2. The semiconductor device according to claim 1, wherein the projecting part has a curved surface.

3. The semiconductor device according to claim 1, wherein the semiconductor substrate includes a groove, the groove having an inner side with a curved surface.

4. The semiconductor device according to claim 3, wherein the projecting part is complementary to the groove.

5. The semiconductor device according to claim 3, wherein the body part has a rectangular shape and covers the groove.

6. The semiconductor device according to claim 3, further comprising a gate insulating layer between the semiconductor substrate and the gate electrode.

7. The semiconductor device according to claim 6, wherein a portion of the gate insulating layer is inside the groove.

8. The semiconductor device according to claim 1, wherein the semiconductor substrate comprises an n-type impurity region, a device isolating layer, and a p-type well.

9. The semiconductor device according to claim 8, wherein the device isolating layer defines an active region.

10. The semiconductor device according to claim 1, further comprising a spacer on opposite sides of the gate electrode.

11. The semiconductor device according to claim 10, further comprising lightly doped drain regions in the substrate under the spacer.

12. The semiconductor device according to claim 1, further comprising a silicide layer on the gate electrode and/or the source/drain regions.

13. A method of fabricating a semiconductor device comprising the steps of:
forming a groove on a semiconductor substrate;
forming a gate electrode on the semiconductor substrate, the gate electrode comprising a body part on the semiconductor substrate and a projecting part projecting downwardly from the body into the groove; and
forming source/drain regions in the semiconductor substrate at opposite sides of the gate electrode.

14. The method of fabricating a semiconductor device according to claim 13, wherein forming the groove comprises:
selectively forming at least one insulating layer on the semiconductor substrate by a thermal oxidation process; and
removing the insulating layer(s).

15. The method of fabricating a semiconductor device according to claim 13, wherein the inner side of the groove has a curved surface.

16. The method of fabricating a semiconductor device according to claim 13, wherein the projecting part of the gate electrode fills the groove.

17. The method of fabricating a semiconductor device according to claim 13, further comprising forming a gate insulating layer on the semiconductor substrate and inside the groove.

18. The method of fabricating a semiconductor device according to claim 13, further comprising forming an n-type impurity region, a device isolating layer, and a p-type well in the semiconductor substrate.

19. The method of fabricating a semiconductor device according to claim 13, further comprising forming a spacer on opposite sides of the gate electrode.

20. The method of fabricating a semiconductor device according to claim 19, further comprising forming lightly doped drain regions in the substrate adjacent to the gate electrode.
